(19) United States
(12) Patent Application Publication
(10) Pub. No.: US 2002/0195654 A1
(43) Pub. Date: Dec. 26, 2002

(54) DMOS transistor and fabricating method thereof

(76) Inventor: Tae-hun Kwon, Bucheon-city (KR)

Correspondence Address: ROTHWELL, FIGG, ERNST & MANBECK, P.C., 1425 K STREET, N.W., SUITE 800, WASHINGTON, DC, 20005, US

(21) Appl. No.: 10/225,187

(22) Filed: Aug. 22, 2002

Related U.S. Application Data
(63) Continuation of application No. 09/421,297, filed on Oct. 20, 1999.

(30) Foreign Application Priority Data
Oct. 26, 1998 (KR) 98-44806

(51) Int. Cl. H01L 29/94; H01L 31/113

(52) U.S. Cl. 257/329

(57) ABSTRACT

A DMOS transistor having high reliability and a fabricating method thereof are described. By the method for fabricating the DMOS transistor, a semiconductor layer of a second conductivity type is formed on a semiconductor substrate of a first conductivity type. A conductive layer is deposited and then the deposited conductive layer is patterned to thereby form a gate electrode and a conductive layer pattern on the semiconductor layer. A body region of the first conductivity type is formed in the semiconductor layer using the conductive layer pattern as a mask. A drain of a second conductivity type is formed in the semiconductor layer, and at the same time a source of the second conductivity type is formed in the body region using the conductive layer pattern as a mask. A highly-doped impurity region for bias is formed in the body region, using the conductive layer pattern as a mask. An interdielectric layer covering the resultant structure is formed. Also, a drain electrode and a source electrode connected to the drain and the source respectively are formed through a contact hole formed in the interdielectric layer.

### CROSS-REFERENCE TO RELATED APPLICATION

The present application is a continuation of U.S. application Ser. No. 09/421,297, filed Oct. 20, 1999.

### BACKGROUND OF THE INVENTION

1. Field of the Invention

The present invention relates to a power semiconductor device and a fabrication method thereof, and more particularly, to a double diffused MOSFET (DMOS) transistor having high reliability, and to a fabricating method thereof.

2. Description of the Related Art

Compared to a bipolar transistor, a MOS field effect transistor (MOSFET) has a high input impedance and is a unipolar device. Hence a MOSFET has a high power gain, can be driven by a very simple gate drive circuit, and has no temporal delay caused by accumulation or recombination due to a small number of carriers during turn-off of the device. Thus, the uses of MOSFETs are spreading to applications such as switching mode power supplies, lamp ballasts, and motor driving circuits. A widely used type of MOSFET is a DMOS structure in which planar diffusion technology is used.

FIG. 1 is a sectional view of a conventional DMOS structure.

Referring to FIG. 1, an n-type well 4 is formed on a p-type semiconductor substrate 2, and a drain 12 highly-doped with an n-type impurity is formed in the n-type well. A drain electrode 22 is also formed. Also, a p-type body region 6 is formed in the n-type well spaced apart from the drain 12 by a predetermined distance, and a p+ impurity region 8 for controlling the bias of the body region and an adjoining source 10 highly-doped with an n-type impurity are formed in the body region.

Also, a gate electrode 16 is formed on the semiconductor substrate, with a gate insulating layer 14 interposed therebetween. An interdielectric layer 18 for insulating a transistor from other conductive layers is formed on the resultant structure, a source electrode 20 connected to the p+ impurity region 8 for bias and n+ source 10 are formed through a contact hole formed in the interdielectric layer.

In switching operation a typical DMOS device, when the device is turned off, has current due to the electromotive force of a coil and displacement current between a drain and a body region flows out through the body region. Here, current due to the electromotive force of a coil is prevented from flowing into the DMOS device by connecting an external diode to the outside. However, if a zener diode Z1 (of FIG. 1) is formed between the drain and the body regions instead of using an external diode for preventing the electromotive force due to the coil, the material cost is reduced, and the manufacturing process is simplified.

Also, when current flows through the body region, the same bias is applied to the body region and the source to prevent the PN junction of the body region and the source from being turned-on. However, although the same bias is applied to the source and body regions, the voltage drop generated by current flowing through a pinch resistance R_{b} (of FIG. 1) of the body region is higher than the turn-on voltage of the PN junction, and the PN junction between the source and the body regions operates in the forward direction.

When the DMOS device is turned off, a channel disappears, and a voltage in a reverse direction is applied between the body and drain regions, so that the junction between the source and the body regions operates in forward direction, and the source-body region-drain act as the emitter-base-collector of a bipolar transistor, to thereby cause the operation of a parasitic bipolar transistor. When the parasitic bipolar transistor operates, power consumption is increased due to temporal delay during switching, and excessive current flows toward the drain, to thereby break a device.

Meanwhile, when a channel is formed and current flows, electron-hole pairs are generated due to hot electrons. Here, the generated holes (electrons in a PDMOS) move out through the body region. When the voltage drop due to the pinch resistance R_{b} of the body region is more than the turn-on voltage of the PN junction between the body and the source regions, holes are injected into the source. When electrons are injected into the source, the electrons are injected into the body region from the source, to thereby cause secondary breakdown. Secondary breakdown reduces the safe operating area (SOA) of a device, to thereby deteriorate characteristics of the device.

FIG. 2 is a sectional view showing an example of another conventional DMOS, and a structure for minimizing the effect due to a pinch resistance of the body region.

Referring to FIG. 2, a highly-doped body region 7 is formed, to thereby reduce the pinch resistance R_{b,} and a zener diode Z2 is formed in which current flows due to the electromotive force of a coil.

As described above, the current flowing through the pinch resistance R_{b} is due to the electromotive force of the coil, the displacement current, and current due to hot electron-hole pairs. Here, the current due to the electromotive force of the double coil is the greatest. However, a diode is formed under the body region through which the current due to the electromotive force of the coil flows by the highly-doped body region, so that current is prevented from passing through the pinch resistance R_{b.} Thus, the voltage drop due to the current of the coil is interrupted. Also, the voltage drop due to the other two current components is reduced by reducing the pinch resistance of the highly-doped body region.

Thus, operation of the parasitic bipolar transistor is reduced, and the SOA is enlarged, to improve the characteristics of the device.

However, the highly-doped body region 7 must be separately formed, so that a mask must be added. Also, when misalignment occurs during a photo lithographic process, the highly-doped body region effects the channel such that the threshold voltage of the device is changed. Thus, excessive current flows in the other side, to thereby damage the device.

### SUMMARY OF THE INVENTION

It is an object of the present invention to provide a DMOS transistor in which pinch resistance of a body region is reduced without an additional mask, to thereby enhance characteristics and increase reliability.

It is another object of the present invention to provide a method for fabricating the DMOS transistor.

Accordingly, to achieve the first object, In a DMOS transistor, a gate electrode and a conductive layer pattern formed on the semiconductor substrate of a first conductivity type, wherein a gate insulating layer is formed under the gate electrode and semiconductor layer pattern. A semiconductor region of a second conductivity type is formed in the semiconductor substrate. A body region of the first conductivity type is formed in the semiconductor region. A source of the second conductivity type is formed in the body region, and an impurity region is formed in the body region, adjacent to the source. A source electrode connected to the source is formed.

The conductive layer pattern is formed on the semiconductor substrate adjacent to one side of the source, and the gate electrode and the conductive layer pattern are formed of polysilicon.

The DMOS transistor may further comprise a highly-doped buried layer under the body region and contacting the bottom surface of the body region.

The DMOS transistor may also further comprise a drain of the second conductivity type formed in the semiconductor region spaced apart from the body region by a predetermined region.

At this time, the conductive layer pattern is formed on the semiconductor substrate adjacent to one side of the source and drain.

The DMOS transistor may further comprise a drain of the second conductivity type formed on the rear side of the semiconductor substrate.

To achieve the second object, a method for fabricating a DMOS transistor comprising the steps of: (a) forming a semiconductor layer of a second conductivity type on a semiconductor substrate of a first conductivity type; (b) depositing a conductive layer and patterning the deposited conductive layer to thereby form a gate electrode and a conductive layer pattern on the semiconductor layer; (c) forming a body region of the first conductivity type in the semiconductor layer using the conductive layer pattern as a mask; (d) forming a drain of a second conductivity type in the semiconductor layer, and at the same time a source of the second conductivity type in the body region using the conductive layer pattern as a mask; (e) forming a highly-doped impurity region for bias in the body region, using the conductive layer pattern as a mask; (f) forming an interdielectric layer covering the resultant structure; and (g) forming a drain electrode and a source electrode connected to the drain and the source respectively, through a contact hole formed in the interdielectric layer.

The method may further comprise the step of forming a buried impurity layer of the second conductivity type in the semiconductor substrate at a predetermined depth before step (a).

The conductive layer pattern in step (b) is formed on the semiconductor substrate adjacent to one side of the region where the body region and the source are to be formed, or on the semiconductor substrate adjacent to a region where the body region, the source and the drain are to be formed. The gate electrode and the conductive layer pattern are formed of polysilicon.

According to the present invention, pinch resistance R_{b} of a body region can be effectively reduced without adding a mask, and the body region, a source, and a drain are self-aligned, which causes stable device characteristics. A mask for forming the highly-doped body region is also used to form a p-type isolation region, to thereby reduce two masks into one. Also, a diode composed of a body region and a drain is formed under a parasitic bipolar transistor, so that operation of the parasitic bipolar transistor is interrupted when current flows due to the electromotive force of the coil during switching, to thereby increase the reliability of the device.

### BRIEF DESCRIPTION OF THE DRAWINGS

The above objects and advantages of the present invention will become more apparent by describing in detail a preferred embodiment thereof with reference to the attached drawings in which:

FIG. 1 is a sectional view of a conventional DMOS;

FIG. 2 is a sectional view showing an example of another conventional DMOS;

FIG. 3 is a sectional view of a DMOS transistor according to the present invention; and

FIGS. 4 through 9 are sectional views illustrating a method of fabricating a DMOS transistor according to an embodiment of the present invention.

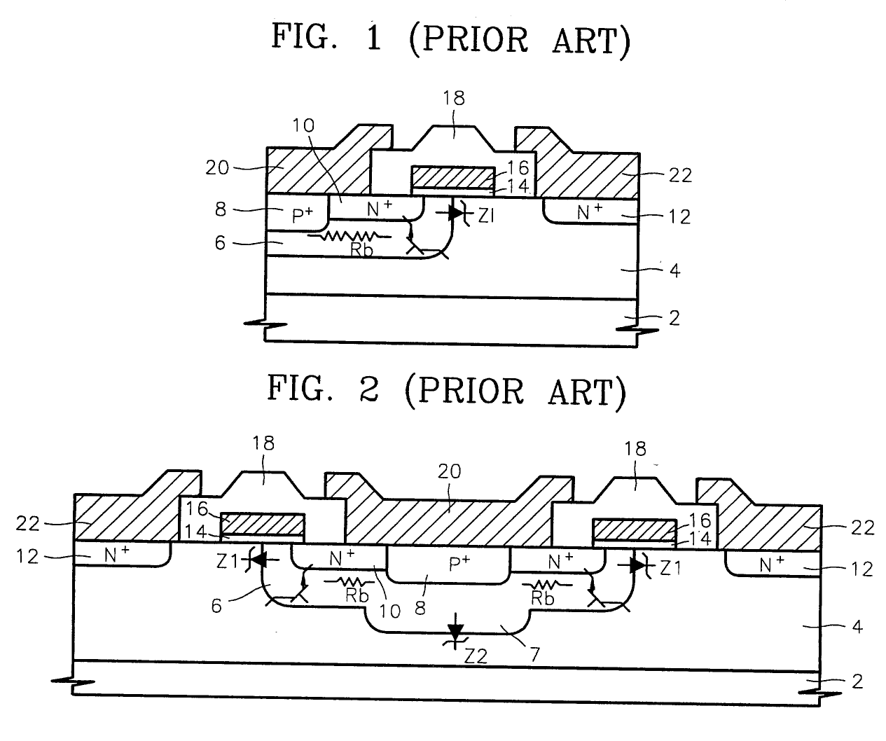

### DESCRIPTION OF THE PREFERRED EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present.

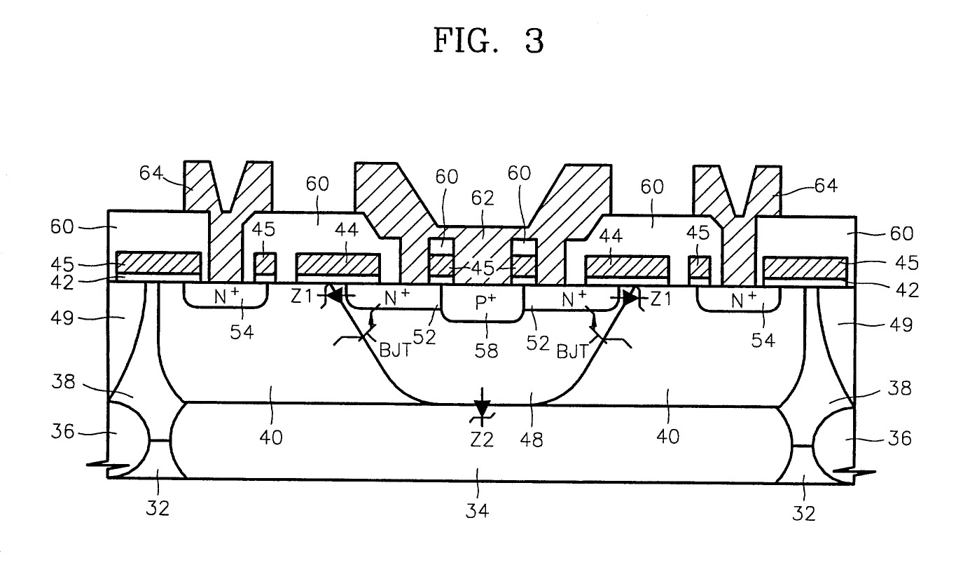

Referring to FIG. 3, a buried impurity layer 34 of a second conductivity type (n-type) and a p-type impurity region 36 for isolation are formed on a semiconductor substrate 32 of a first conductivity type (p-type). An n-type epitaxial layer 38 is formed on the impurity region 36 by a typical epitaxial growth method, and an n-well 40 is formed on the epitaxial layer.

A gate electrode 44 formed of polysilicon and a conductive layer pattern 45 are formed on the semiconductor substrate, interposing a gate insulating layer 42 therebetween.

In addition, a p-type body region 48 is formed in the n-well 40, and an isolation region 49 is formed. One or more n+ sources 52 highly doped with an n-type impurity and a p-type highly-doped impurity region 58 for applying an appropriate bias to the body region 48 are formed in the body region 48. The body region 48, the source, the p-type highly-doped impurity region 58 for bias and drains 54 are formed in self-alignment by a conductive layer pattern 45 and the gate electrode 44 formed on the semiconductor substrate.

Also, an interdielectric layer 60 is formed on the semiconductor substrate. A source electrode 62 connected to the sources 52 and the p-type impurity region 58 for bias, and drain electrodes 64 connected to the drain 54 are formed through a contact hole formed in the interdielectric layer.

The structure of the present invention which is a horizontal DMOS (LDMOS) in FIG. 3, may also be adapted to a vertical DMOS (VDMOS).

A method for fabricating a DMOS transistor according to the present invention will now be described.

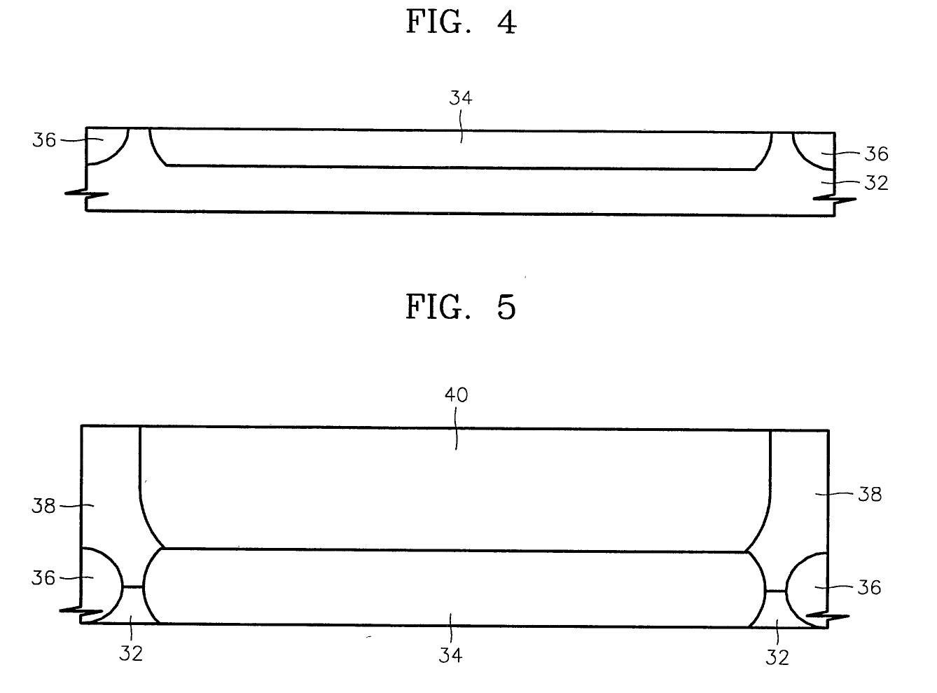

FIGS. 4 through 9 show an example of an n-type DMOS transistor.

Referring to FIG. 4, a conventional photolithographic process is performed on a p-type semiconductor substrate 32, and then n-type impurity ions are implanted with high concentration into a defined region of the semiconductor substrate 32 and diffused to form an N-type buried layer 34. The photolithographic process is performed, and then p-type impurity ions are implanted with a dose of 1×10¹⁴ ions/cm² into a defined region and the implanted impurity ions are diffused, to thereby form a p-type impurity layer 36 for isolation.

Referring to FIG. 5, an n-type epitaxial layer 38 having resistivity of 1˜2Ω/cm is formed on the semiconductor substrate where the n-type buried layer 34 and the p-type impurity layer 36 are formed, using a conventional epitaxial growth method. Here, n-type impurities of the buried layer and p-type impurities of the p-type impurity layer are diffused upward.

Then, a predetermined region is defined through a photolithographic process, and then the n-type impurity ions are implanted into the defined region with a dose of 1×10¹³ ion/cm², and then the implanted ions are diffused to form an n-well 40.

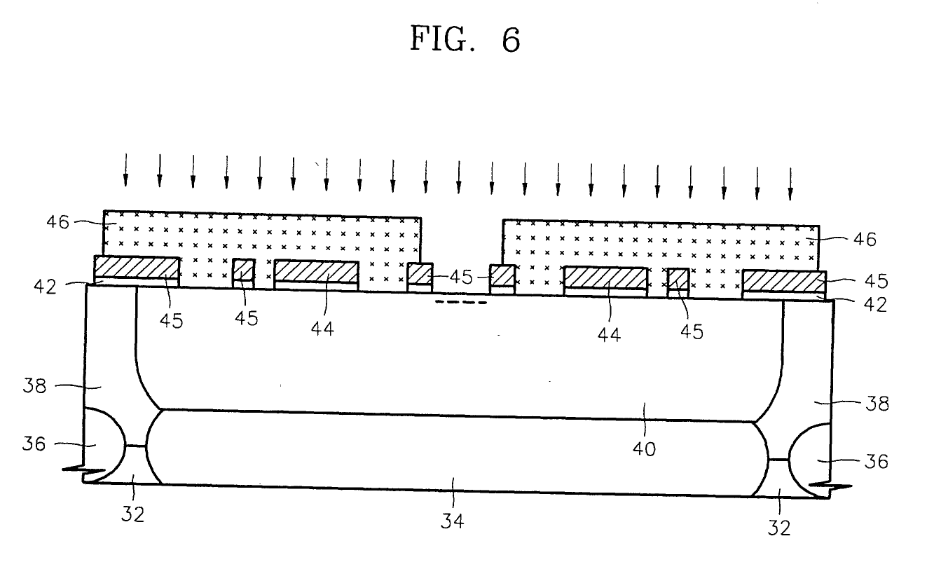

Referring to FIG. 6, a gate insulating layer 42 obtained by growing an oxide layer to a thickness of 200˜500 Å is formed on the resultant structure where the epitaxial layer 38 and the n-type well 40 are formed. Polysilicon doped with an impurity is deposited on the gate insulating layer 42 to a thickness of 3,000˜5,000 Å. The polysilicon layer is patterned using the photolithographic process, to thereby form a gate electrode 44 and a conductive layer pattern 45. The conductive layer pattern 45 is for forming a source, a body region and drain in self-alignment in a next process.

Then, a photosensitive layer pattern 46 defining a body region and an isolation region is formed. P-type impurities are implanted with a dose of 1×10¹⁵ ions/cm². Here, the conductive layer pattern 45 is an ion implantation mask, so that although a small misalignment occurs during the photolithographic process for forming the photosensitive layer pattern 46, the body region and the isolation region can be formed in self-alignment.

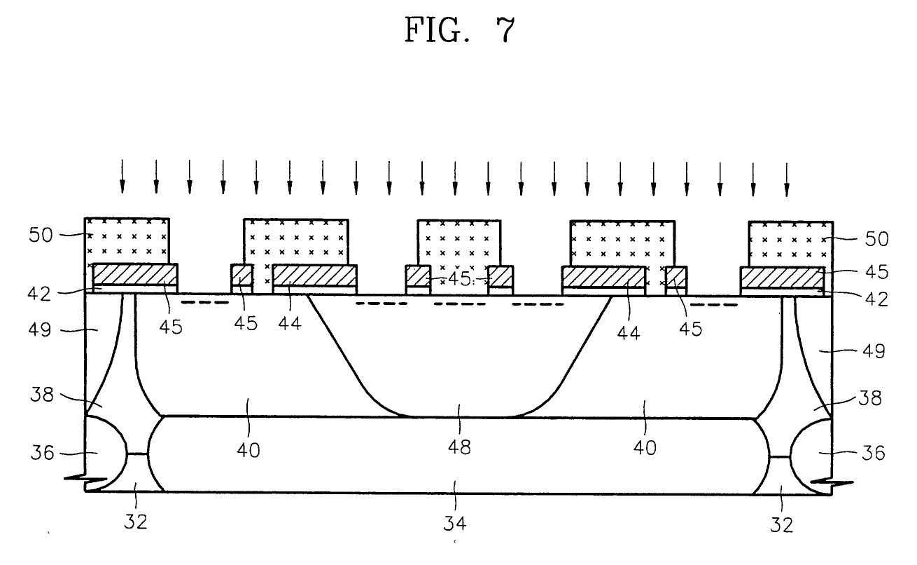

Referring to FIG. 7, a predetermined diffusion process is performed after removing the photosensitive layer pattern, a body region 48 is formed. Then, a photosensitive layer pattern 50 defining a source and a drain is formed through a typical photolithographic process. N-type impurity ions are implanted into the defined region with a dose of 1×10¹⁵ ions/cm². Here, the conductive layer pattern 45 act as a mask, so that the source and the drain are formed in self-alignment even though a small misalignment occurs during the photolithographic process for forming the photosensitive layer pattern 50.

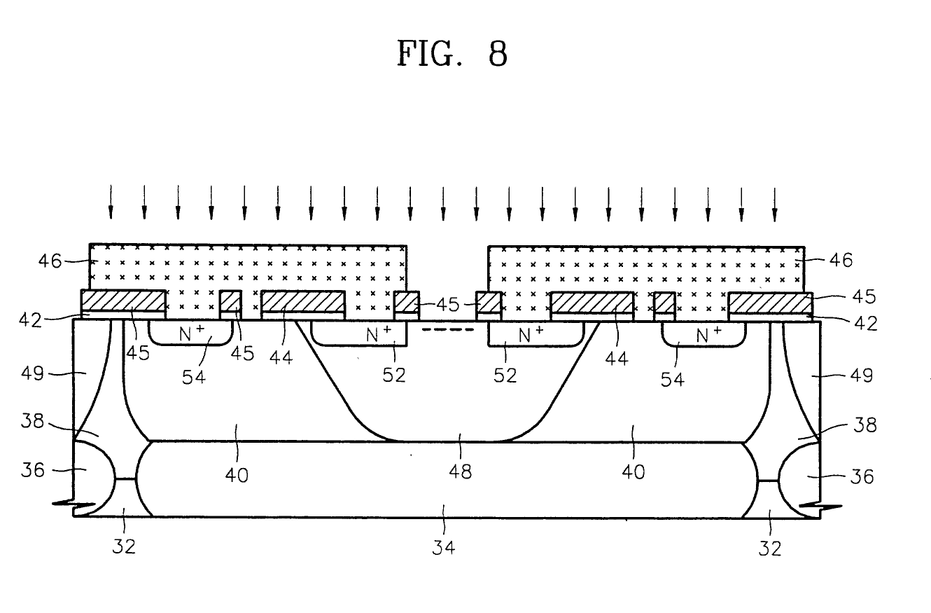

Referring to FIG. 8, the photosensitive layer pattern is removed and a predetermined diffusion process is performed to form a source 52 and a drain 54. Then, a photosensitive layer pattern 56 defining a body contact region is formed through a photo lithographic process, and then the p-type impurity ion is implanted into the defined region with a dose of 1×10¹⁵ ions/cm². Here, the conductive layer pattern acts as a mask, so that a small misalignment may occur during the photo lithographic process.

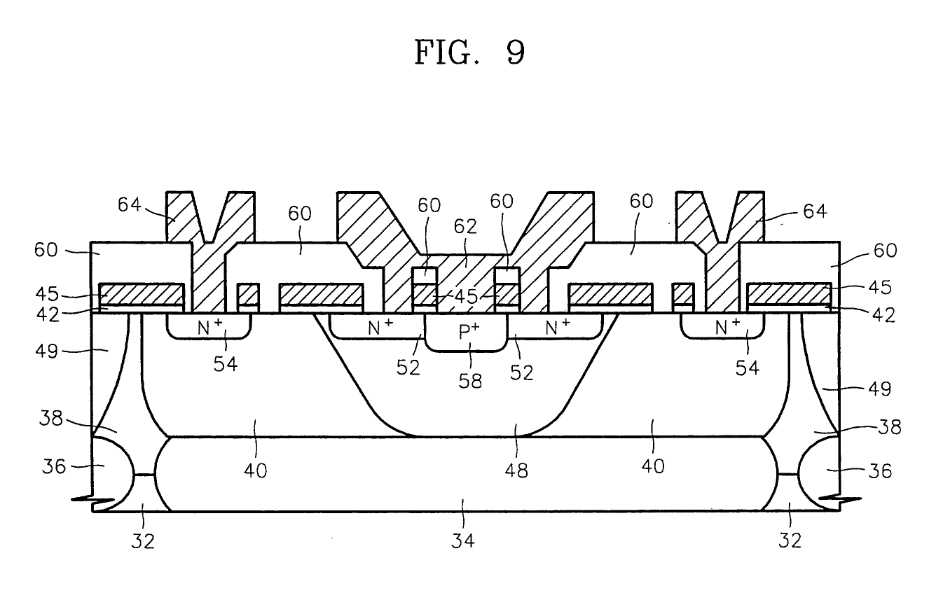

Referring to FIG. 9, the photosensitive layer pattern is removed, and then a body contact region 58 is formed through diffusion, and an interdielectric layer 60 is formed on the entire surface of the resultant structure. The interdielectric layer is patterned using a photolithographic process, to thereby contact holes exposing the body contact region 58, the sources 52 and the drains 54. Subsequently, a metal layer is deposited on the resultant structure and the resultant structure is patterned by a photolithographic process, to thereby form a source electrode 62 and a drain electrode 64.

According to the DMOS transistor of the present invention and a fabricating method thereof, pinch resistance R_{b} of a body region can be effectively reduced without adding a mask. In a typical process of fabricating a DMOS, a body region and a source are diffused from a starting point, so that a highly-doped body region cannot be formed. Thus, the pinch resistance of the body region is increased, so that a highly-doped body region must be added to reduce the pinch resistance, and thus an additional mask is required. However, according to the present invention, a diffusion start point of the body region is different from that of a source, so that ion-implantation for the body region is performed with a high dose and then diffusion is performed. Then, source ion implantation is performed in the body region of a portion having low concentration due to diffusion into the side. Thus, the concentration of the channel can be maintained at a low level without an additional mask and the pinch resistance can be reduced.

The body region-source-drain are self-aligned by the conductive layer pattern 45 and the gate electrode 44, which causes stable device characteristics. At the case of the present invention, misalignment is very important for the length of a channel during implantation of source into a lightly-doped portion of the body region. According to the present invention, when the polysilicon layer is etched to form a gate, the conductive layer pattern is also formed to form the body region, the source and the drain to be self-aligned, so that the distance between the regions is constant regardless of the photolithographic process, to thereby minimize a change in the threshold voltage Vₜₕ, on-resistance R_{dSon} and l_{dss}.

The mask for forming the highly-doped body region is used to form a p-type isolation region, to thereby reduce two masks in one.

A diode composed of a body region and a drain is formed under the parasitic bipolar transistor, so that operation of the parasitic bipolar transistor is interrupted when current flows due to the electromotive force of the coil during switching, to thereby increase the reliability of the device.

As a result, according to the present invention, a stable DMOS device having good characteristics can be realized without an additional mask.

It should be understood that the invention is not limited to the illustrated embodiment and that many changes and modifications can be made within the scope of the invention by a person skilled in the art.

What is claimed is:

1. A DMOS transistor comprising:
a semiconductor substrate of a first conductivity type;
a gate electrode and a conductive layer pattern formed on the semiconductor substrate, wherein a gate insulating layer is formed under the gate electrode and semiconductor layer pattern;
a semiconductor region of a second conductivity type formed in the semiconductor substrate;
a body region of the first conductivity type formed in the semiconductor region;
a source of the second conductivity type formed in the body region;
an impurity region formed in the body region, adjacent to the source; and
a source electrode connected to the source,
wherein the body region, source and impurity region are self-aligned by the gate electrode and the conductive layer pattern.

2. The DMOS transistor of claim 1, wherein the gate electrode and the conductive layer pattern are formed of polysilicon.

3. The DMOS transistor of claim 1, further comprising a highly-doped buried layer under the body region and contacting the bottom surface of the body region.

4. The DMOS transistor of claim 1, further comprising a drain of the second conductivity type formed in the semiconductor region spaced apart from the body region by a predetermined region.

5. The DMOS transistor of claim 1, wherein the conductive layer pattern is formed on the semiconductor substrate adjacent to one side of the source and drain.

6. The DMOS transistor of claim 1, further comprising a drain of the second conductivity type formed on the rear side of the semiconductor substrate.

7. The DMOS transistor of claim 1, wherein the conductive layer pattern is formed on the semiconductor substrate adjacent to one side of the source.
